(19) United States
(12) Patent Application Publication
(10) Pub. No.: US 2026/0156944 A1
(43) Pub. Date: Jun. 4, 2026

(54) SEMICONDUCTOR STRUCTURE AND PREPARATION METHOD THEREOF

(71) Applicant: Fujian Jinhua Integrated Circuit Co., Ltd., Fujian (CN)

(72) Inventors: Linghui LIN, Fujian (CN); Fengnian CAI, Fujian (CN)

(73) Assignee: Fujian Jinhua Integrated Circuit Co., Ltd., Fujian (CN)

(21) Appl. No.: 19/403,292

(22) Filed: Nov. 28, 2025

(30) Foreign Application Priority Data
Nov. 29, 2024 (CN) 202411745857.6

(51) Int. Cl. H10D 89/10; H10D 1/00; H10D 1/68

(52) U.S. Cl. CPC H10D 89/10; H10D 1/041; H10D 1/692

(57) ABSTRACT

The present disclosure relates to a semiconductor structure and a preparation method thereof, which relates to the field of integrated circuit design and manufacturing technology, where a plurality of bottom electrodes are located on a substrate; a support layer is in direct contact with sidewalls of the plurality of bottom electrodes, and the support layer includes a wavy border; a plurality of openings are located between adjacent bottom electrodes, and arranged in an array at intervals along a first direction and a second direction, where the opening has a first dimension; where when viewed from a top view, the wavy border includes a plurality of peaks and a plurality of valleys, with a distance between adjacent peaks having a second dimension, and the second dimension is greater than the first dimension.

### CROSS-REFERENCE TO RELATED APPLICATION

This application claims priority to Chinese Patent Application No. 202411745857.6, filed on Nov. 29, 2024, which is hereby incorporated by reference in its entirety.

### TECHNICAL FIELD

The present disclosure relates to the field of integrated circuit design and manufacturing technology, and in particular, to a semiconductor structure and a preparation method thereof.

### BACKGROUND

With the rapid development of semiconductor technology, the market has an increasingly high requirement for the integration, performance, and reliability of integrated circuits. Moore's Law has driven the development of the semiconductor industry, continuously improving the performance of memories and gradually reducing costs.

However, the constantly increasing integration requirements have led to the reduction in a volume of individual storage cells within the memory, as well as the pitch between a storage array region and a peripheral logic circuit region, causing a continuous decline in the yield and reliability of storage cells at edges of the storage array.

### SUMMARY

Based on the above, it is necessary to provide a semiconductor structure and a preparation method thereof aiming at the problem in the aforementioned Background, which can at least improve the morphology quality of the cell pattern at the edge of the array region without increasing the volume of the semiconductor structure and without reducing the cell density, thereby improving the yield, performance, and reliability of the semiconductor structure.

According to various embodiments of the present disclosure, a first aspect of the present disclosure provides a semiconductor structure, including: a substrate, a plurality of bottom electrodes, a support layer, and a plurality of openings; where the plurality of bottom electrodes are located on the substrate; the support layer is in direct contact with sidewalls of the plurality of bottom electrodes, and the support layer includes a wavy border; the plurality of openings are located between adjacent bottom electrodes, and arranged in an array at intervals along a first direction and a second direction, where the opening has a first dimension; where when viewed from a top view, the wavy border includes a plurality of peaks and a plurality of valleys, with a distance between adjacent peaks having a second dimension, and the second dimension is greater than the first dimension.

The semiconductor structure in the above embodiments can increase the pitch between the peak of the support layer and the nearest opening without increasing a volume of the semiconductor structure and without reducing the cell density of the bottom electrode and the support degree of the support layer. This improves the morphology quality of the opening pattern at the edge of the array region of the bottom electrodes 11, thereby improving the yield, performance, and reliability of the semiconductor structure.

A second aspect of the present disclosure provides a semiconductor structure including: a substrate, a plurality of bottom electrodes, a support layer, and a plurality of openings; where the plurality of bottom electrodes are located on the substrate; the support layer is in direct contact with sidewalls of the plurality of bottom electrodes, and the support layer includes a wavy border; the plurality of openings are located between adjacent bottom electrodes, and arranged in an array at intervals along a first direction and a second direction; where when view from a top view, the wavy border includes a plurality of peaks and a plurality of valleys, and there is a first preset pitch between the valley and a nearest opening; and there is a second preset pitch between the valley and a nearest bottom electrode; where the first preset pitch is greater than the second preset pitch.

The semiconductor structure in the above embodiments can increase the pitch between the peak of the support layer and the nearest opening without increasing a volume of the semiconductor structure and without reducing the cell density of the bottom electrode and the support degree of the support layer. This improves the morphology quality of the bottom electrode and the opening pattern at the edge of the array region of the bottom electrodes, thereby improving the yield, performance, and reliability of the semiconductor structure.

A third aspect of the present disclosure provides a semiconductor structure including: a substrate, a plurality of bottom electrodes, a support layer, and a plurality of openings; where the plurality of bottom electrodes are located on the substrate; the support layer is in direct contact with sidewalls of the plurality of bottom electrodes, and the support layer includes a wavy border; the plurality of openings are located between adjacent bottom electrodes, and arranged in an array at intervals along a first direction and a second direction, and there is a first pitch between adjacent openings; where a minimum pitch between the wavy border and a nearest opening along the second direction is greater than the first pitch.

The semiconductor structure in the above embodiments can increase the pitch between the peak of the support layer and the nearest opening without increasing a volume of the semiconductor structure and without reducing the cell density of the bottom electrode and the support degree of the support layer. This improves the morphology quality of the bottom electrode and the opening pattern at the edge of the array region of the bottom electrodes, thereby improving the yield, performance, and reliability of the semiconductor structure.

A fourth aspect of the present disclosure provides a semiconductor structure preparation method, including:
providing a substrate including a stacked structure, where the stacked structure includes a first sacrificial layer, a first support layer, a second sacrificial layer, and a second support layer stacked in sequence along a direction away from the substrate;
forming a plurality of bottom electrodes which penetrate the stacked structure along a direction perpendicular to the substrate;
removing a portion of the first support layer and a portion of the second support layer to obtain a support layer including a plurality of openings, where the remaining first support layer and the remaining second support layer are used to form the support layer which directly contacts with sidewalls of the plurality of bottom electrodes, and including a wavy border; and the plurality of openings are located between adjacent bottom electrodes, and arranged in an array at intervals along a first direction and a second direction; and
removing the first sacrificial layer and the second sacrificial layer.

The semiconductor structure preparation method in the above embodiments can obtain the support layer which directly contacts with the sidewalls of the plurality of bottom electrodes after removing the first sacrificial layer and the second sacrificial layer, where the plurality of bottom electrodes are supported by using the support layer, which ensures that the array of bottom electrodes including the plurality of openings is firmly standing on the substrate. The support layer is arranged to include the wavy border, which facilitates increasing the pitch between the peak of the support layer and the nearest opening without increasing a volume of the semiconductor structure and without reducing the cell density of the bottom electrode and the support degree of the support layer. This improves the morphology quality of the opening pattern at the edge of the array region of the bottom electrodes, thereby improving the yield, performance, and reliability of the semiconductor structure.

### BRIEF DESCRIPTION OF THE DRAWINGS

In order to more clearly describe technical solution in embodiments of the present disclosure, in the following, the drawings that need to be used in the description of the embodiments will be briefly introduced. Apparently, the drawings in the following description are a part of the embodiments of the present disclosure. For persons of ordinary skill in the art, other drawings can be obtained based on these drawings without creative efforts.

FIG. 1A is a schematic top view of a semiconductor structure in an embodiment of the present application.

FIG. 1B is a schematic diagram of a cross-sectional structure of the semiconductor structure in FIG. 1A taken along a direction perpendicular to a top surface of a substrate.

FIG. 2 is a flowchart of a semiconductor structure preparation method provided in an embodiment of the present disclosure.

FIG. 3A is a schematic diagram of a longitudinal cross-sectional structure of the semiconductor structure obtained in step S20 of a semiconductor structure preparation method in an embodiment of the present disclosure.

FIG. 3B is a schematic top view of FIG. 3A.

FIG. 4A is a schematic diagram of a longitudinal cross-sectional structure of a semiconductor structure obtained after forming a bottom electrode in step S40 of a semiconductor structure preparation method in an embodiment of the present disclosure.

FIG. 4B is a schematic top view of FIG. 4A.

FIG. 5A is a schematic diagram of a longitudinal cross-sectional structure of a semiconductor structure obtained after forming a support layer with a wavy border in step S60 of a semiconductor structure preparation method in an embodiment of the present disclosure.

FIG. 5B is a schematic top view of FIG. 5A.

FIG. 6A is a schematic diagram of a longitudinal cross-sectional structure of a semiconductor structure obtained after removing a first sacrificial layer and a second sacrificial layer in step S80 of a semiconductor structure preparation method in an embodiment of the present disclosure.

FIG. 6B is a schematic top view of FIG. 6A.

Annotations of the reference numbers:
1000: semiconductor structure; 20: support layer; 101: peak; 102: valley; 11: bottom electrode; 12: opening; 21: first support layer; 22: second support layer; 201: first sacrificial layer; 202: second sacrificial layer; 100: substrate; S1 first dimension; S2: second dimension; S3: third dimension; P0: first pitch; P1: second pitch; P2: third pitch; P3: fourth pitch; SP1: first preset pitch; and SP2: second preset pitch.

### DESCRIPTION OF THE EMBODIMENTS

For the convenience of understanding the present disclosure, a more comprehensive description of the present disclosure will be provided below with reference to the relevant drawings. Preferred embodiments of the present disclosure are shown in the drawings. However, the present disclosure can be implemented in many different forms and is not limited to the embodiments described herein. On the contrary, the purpose of providing these embodiments is to make the content disclosed by the present disclosure more thorough and comprehensive.

Unless otherwise defined, all technical and scientific terms used herein have the same meanings as those commonly understood by those skilled in the art belonging to the present disclosure. The terms used in the present disclosure are only for the purpose of describing specific embodiments and are not intended to limit the present disclosure.

It should be understood that when a component or a layer is referred to as “on . . . ”, “adjacent to . . . ”, “connected to”, or “coupled to” another component or another layer, it may be directly on, adjacent to, connected to, or coupled to another component or another layer, or there may be an intervening component or layer. On the contrary, when a component is referred to as “directly on . . . ”, “directly adjacent to . . . ”, “in direct connected with”, or “directly coupled to” another component or another layer, there are no intervening component or layer. It should be understood that although the terms first, second, third, etc. may be used to describe various elements, components, regions, layers, doping types, and/or portions, these elements, components, regions, layers, doping types, and/or portions should not be limited by these terms. These terms are only used to distinguish an element, a component, a region, a layer, a doping type or a portion from another element, another component, another region, another layer, another doping type or another portion. Therefore, without departing from the teachings of the present disclosure, a first element, a first component, a first region, a first layer, a first doping type, or a first portion discussed below may be referred to as a second element, a second component, a second region, a second layer, or a second portion.

Spatial relationship terms such as “below . . . ”, “under . . . ”, “bottom”, “underneath . . . ”, “above . . . ”, “top”, etc., can be used herein to describe a relationship between an element or a feature and another element or feature shown in the drawings.

It should be noted that the drawings provided in the embodiments only illustrate the basic concept of the present disclosure in a schematic manner. Although the drawings only show components related to the present disclosure and are not drawn according to the actual number, shape, and dimension of components during implementation, the form, quantity, and proportion of each component during actual implementation can be arbitrarily changed, and the component layout may also be more complex.

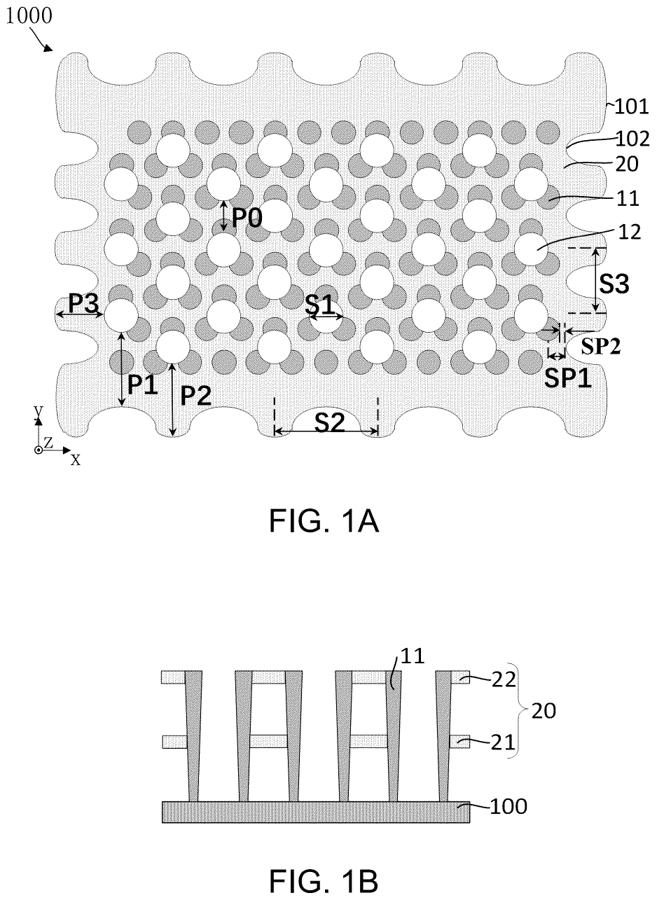

Please refer to FIG. 1A-FIG. 1B. In some embodiments, a semiconductor structure 1000 is provided, including: a substrate 100, a plurality of bottom electrodes 11, a support layer 20, and a plurality of openings 12; where the plurality of bottom electrodes 11 are located on the substrate 100; the support layer 20 is in direct contact with sidewalls of the plurality of bottom electrodes 11, and the support layer 20 includes a wavy border; the plurality of openings 12 are located between adjacent bottom electrodes 11, and arranged in an array at intervals along a first direction (e.g., an X-axis direction) and a second direction (e.g., a Y-axis direction), the opening 12 has a first dimension S1 along the first direction; when viewed from a top view, for example, in a cross-section parallel to a Z-axis direction, the wavy border includes a plurality of peaks 101 and a plurality of valleys 102, with a distance between adjacent peaks 101 along the first direction having a second dimension S2, and the second dimension is greater than the first dimension S1.

Exemplarily, please continue to refer to FIG. 1A-FIG. 1B, through using the support layer 20 to support the plurality of bottom electrodes 11, it ensures that an array of the bottom electrodes 11 including the plurality of openings 12 is firmly standing on the substrate 100. By arranging the support layer 20 to include the wavy border, where when viewed from a top view, the wavy border includes the plurality of peaks 101 and the plurality of valleys 102, and the distance between adjacent peaks 101 along the first direction has the second dimension S2, and the second dimension S2 is greater than the first dimension S1, it facilitates increasing the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11, thereby improving the yield, performance, and reliability of the semiconductor structure 1000.

In some embodiments, a semiconductor structure is provided, further including a top electrode located on a side of the bottom electrode facing away from the substrate, and a dielectric layer located between the top electrode and the bottom electrode. The bottom electrode, the dielectric layer, and the top electrode are used together to form a capacitor. Materials of the bottom electrode and the top electrode may be the same or different. The material of the bottom electrode may include but is not limited to at least one of indium tin oxide, copper, tungsten, aluminum, copper alloy, titanium, titanium nitride, niobium nitride, tantalum nitride, etc. The material of the top electrode may include but is not limited to at least one of indium tin oxide, copper, tungsten, aluminum, copper alloy, titanium, titanium nitride, niobium nitride, tantalum nitride, etc. The material of the dielectric layer may be formed from a material with a high-k (k≥3.9) dielectric constant. For example, the material of the dielectric layer may include but is not limited to at least one of aluminum oxide (Al₂O₃), hafnium oxide (HfO₂), hafnium oxynitride (HfON), zirconium oxide (ZrO₂), tantalum oxide (Ta₂O₅), titanium oxide (TiO₂), or strontium titanium oxide (SrTiO₃), etc.

It should be noted that, in the embodiments of the present application, the first direction may be the X-axis direction, and the second direction may be the Y-axis direction. When ignoring that a top surface of the substrate may be not absolute flatness, both the X-axis direction and the Y-axis direction are parallel to the top surface of the substrate, and the Z-axis is perpendicular to the top surface of the substrate.

Please continue to refer to FIG. 1A. In some embodiments, the wavy border includes a first wavy border extending along the first direction and a second wavy border extending along the second direction, which facilitates arranging the sidewall of the support layer 20 surrounding the array region of the bottom electrodes 11 as the wavy border, thereby improving the morphology quality of the adjacent openings 12 of the sidewall of the support layer 20 surrounding the array region of the bottom electrodes 11.

Please continue to refer to FIG. 1A. In some embodiments, the second dimension S2 spans three bottom electrodes 11 along the first direction, which facilitates the placement of centers of two openings 12 at peak regions of two adjacent peaks 101 of the support layers 20 along the first direction. This design increases the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11 and reduces the morphology designing complexity of the wavy border of the support layer 20.

Please continue to refer to FIG. 1A. In some embodiments, a distance between adjacent peaks 101 of the first wavy border along the first direction has the second dimension S2, and a distance between adjacent peaks 101 of the second wavy border along the second direction has a third dimension S3. Among them, the first dimension S1<the third dimension S3<the second dimension S2. This design facilitates setting the morphology of the wavy border of the support layer 20 according to the distribution of the openings 12 in the array region of the bottom electrodes 11, so that adjacent peaks 101 of the first wavy border extending along the first direction span three bottom electrodes 11, and adjacent peaks 101 of the second wavy border extending along the second direction span three bottom electrodes 11.

Please continue to refer to FIG. 1A. In some embodiments, there is a first pitch P0 between adjacent openings 12 along the second direction. The first pitch P0 may be a minimum pitch between adjacent openings 12 along the second direction. In the second direction, a minimum pitch between the wavy border of the support layer 20 and a nearest opening 12 is greater than the first pitch P0. For example, there is a second pitch P1 between the valley 102 of the first wavy border and the nearest opening 12 along the second direction, where P1 may be a minimum pitch between the valley 102 of the first wavy border and the nearest opening 12, P1>P0. There is a third pitch P2 between the peak 101 of the first wavy border and the nearest opening 12 along the second direction, where P2 may be a minimum pitch between the peak 101 of the first wavy border and the nearest opening 12, P2>P0. Thus, the pitches between the peaks 101 of the wavy border of the support layer 20 and the nearest openings 12 are all greater than the pitches between adjacent openings 12, thereby ensuring the morphology quality of all opening patterns at the edge of the array region of the bottom electrodes 11.

Please continue to refer to FIG. 1A. In some embodiments, there is a fourth pitch P3 between the peak 101 of the second wavy border and the nearest opening 12 along the first direction, where P3 may be a maximum pitch between the second wavy border and the nearest opening 12 along the first direction, P3>P0. Thus, the pitch between the peak 101 of the second wavy border extending along the second direction and the nearest opening 12 along the first direction is greater than the first pitch P0. This design increases the pitch between the peak 101 of the second wavy border of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11.

Please continue to refer to FIG. 1A. In some embodiments, there is a first preset pitch SP1 between the valley 102 and a nearest opening 12; and there is a second preset pitch SP2 between the valley 102 and a nearest bottom electrode 11. This design ensures the morphology quality of the opening pattern at the edge of the array region of the bottom electrodes 11, while simultaneously guaranteeing the morphology quality of the bottom electrode 11 at the edge of the array region of the bottom electrodes 11.

In some embodiments, the first preset pitch SP1 may be smaller than the second preset pitch SP2.

In some other embodiments, the first preset pitch SP1 may be greater than the second preset pitch SP2.

Please refer to FIG. 1A-FIG. 1B. In some embodiments, a semiconductor structure 1000 is provided, including: a substrate 100, a plurality of bottom electrodes 11, a support layer 20, and a plurality of openings 12; where the plurality of bottom electrodes 11 are located on the substrate 100; the support layer 20 is in direct contact with sidewalls of the plurality of bottom electrodes 11, and the support layer 20 includes a wavy border; the plurality of openings 12 are located between adjacent bottom electrodes 11, and arranged in an array at intervals along a first direction and a second direction; among them, when view from a top view, the wavy border includes a plurality of peaks 101 and a plurality of valleys 102, and there is a first preset pitch SP1 between the valley 102 and a nearest opening 12; and there is a second preset pitch SP2 between the valley 102 and a nearest bottom electrode 11.

Please continue to refer to FIG. 1A-FIG. 1B, through using the support layer 20 to support the plurality of bottom electrodes 11, it ensures that the array of the bottom electrodes 11 including the plurality of openings 12 is firmly standing on the substrate 100. By arranging the support layer 20 to include the wavy border, when viewed from the top view, the wavy border includes the plurality of peaks 101 and the plurality of valleys 102, there is the first preset pitch SP1 between the valley 102 and the nearest opening 12; and there is the second preset pitch SP2 between the valley 102 and the nearest bottom electrode 11, it facilitates increasing the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the pattern of the opening 12 and the bottom electrode 11 at the edge of the array region of the bottom electrodes 11, thereby improving the yield, performance, and reliability of the semiconductor structure 1000.

Please continue to refer to FIG. 1A. In some embodiments, the opening 12 has a first dimension S1 along the first direction; a distance between adjacent peaks 101 along the first direction has a second dimension S2, and the second dimension S2 is greater than the first dimension S1. Thus, peak regions of adjacent peaks 101 of the wavy border of the support layer 20 are aligned as much as possible with nearest openings 12 at the edge of the array region of the bottom electrodes 11. This design increases the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11.

Please continue to refer to FIG. 1A. In some embodiments, there is a first pitch P0 between adjacent openings 12 along the second direction; and a minimum pitch between the wavy border and a nearest opening 12 along the second direction is greater than the first pitch P0. For example, there is a second pitch P1 between the valley 102 of the first wavy border and the nearest opening 12 along the second direction, where P1 may be a minimum pitch between the valley 102 of the first wavy border and the nearest opening 12, P1>P0. There is a third pitch P2 between the peak 101 of the first wavy border and the nearest opening 12 along the second direction, where P2 may be a minimum pitch between the peak 101 of the first wavy border and the nearest opening 12, P2>P0. Thus, the pitches between the peaks 101 of the wavy border of the support layer 20 and the nearest openings 12 are greater than pitches between adjacent openings 12, thereby ensuring the morphology quality of all opening patterns at the edge of the array region of the bottom electrodes 11.

Please refer to FIG. 1A-FIG. 1B. In some embodiments, a semiconductor structure 1000 is provided, including: a substrate 100, a plurality of bottom electrodes 11, a support layer 20, and a plurality of openings 12; where the plurality of bottom electrodes 11 are located on the substrate 100; the support layer 20 is in direct contact with sidewalls of the plurality of bottom electrodes 11, and the support layer 20 includes a wavy border; the plurality of openings 12 are located between adjacent bottom electrodes 11, and arranged in an array at intervals along a first direction and a second direction, and there is a first pitch P0 between adjacent openings 12; where a minimum pitch between the wavy border and a nearest opening 12 along the second direction is greater than the first pitch P0.

Exemplarily, please continue to refer to FIG. 1A-FIG. 1B, through using the support layer 20 to support the plurality of bottom electrodes 11, it ensures that the array of the bottom electrodes 11 including the plurality of openings 12 is firmly standing on the substrate 100. By arranging the support layer 20 to include the wavy border, with the minimum pitch between the wavy border and the nearest opening 12 along the second direction being greater than the first pitch P0, it facilitates increasing the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the pattern of the bottom electrode 11 and the opening 12 at the edge of the array region of the bottom electrodes 11, thereby improving the yield, performance, and reliability of the semiconductor structure 1000.

Please continue to refer to FIG. 1A. In some embodiments, the opening 12 has a first dimension S1 along the first direction, and when viewed from a top view, the wavy border includes a plurality of peaks 101 and a plurality of valleys 102; a distance between adjacent peaks 101 along the first direction has a second dimension S2, and the second dimension S2 is greater than the first dimension S1. Thus, peak regions of adjacent peaks 101 of the wavy border of the support layer 20 are aligned as much as possible with nearest openings 12 at the edge of the array region of the bottom electrodes 11. This design increases the pitch between the peak 101 of the support layer 20 and the nearest opening 12 without increasing a volume of the semiconductor structure 1000 and without reducing the cell density of the bottom electrode 11 and the support degree of the support layer 20, thereby improving the morphology quality of the opening pattern at the edge of the array region of the bottom electrodes 11.

Please continue to refer to FIG. 1A. In some embodiments, when viewed from a top view, the wavy border includes a plurality of peaks 101 and a plurality of valleys 102, and there is a first preset pitch SP1 between the valley 102 and a nearest opening 12; and there is a second preset pitch SP2 between the valley 102 and a nearest bottom electrode 11. This design ensures the morphology quality of the opening pattern at the edge of the array region of the bottom electrodes 11, while simultaneously guaranteeing the morphology quality of the bottom electrode 11 at the edge of the array region of the bottom electrodes 11.

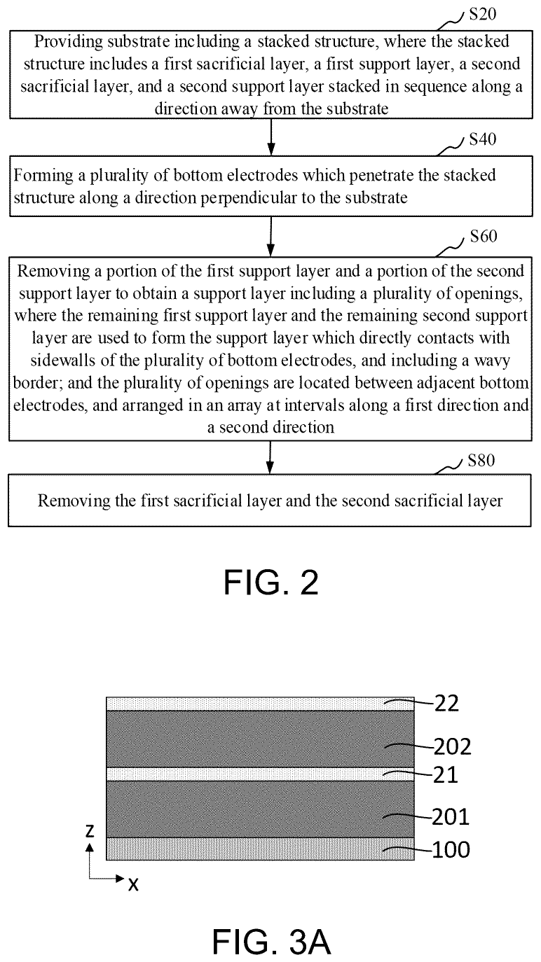

Please refer to FIG. 2. In some embodiments, a semiconductor structure preparation method is provided, which includes the following steps:
step S20: providing a substrate including a stacked structure, where the stacked structure includes a first sacrificial layer, a first support layer, a second sacrificial layer, and a second support layer stacked in sequence along a direction away from the substrate;
step S40: forming a plurality of bottom electrodes which penetrate the stacked structure along a direction perpendicular to the substrate;
step S60: removing a portion of the first support layer and a portion of the second support layer to obtain a support layer including a plurality of openings, where the remaining first support layer and the remaining second support layer are used to form the support layer which directly contacts with sidewalls of the plurality of bottom electrodes, and including a wavy border; and the plurality of openings are located between adjacent bottom electrodes, and arranged in an array at intervals along a first direction and a second direction;
step S80: removing the first sacrificial layer and the second sacrificial layer.

Where the semiconductor structure may include a memory.

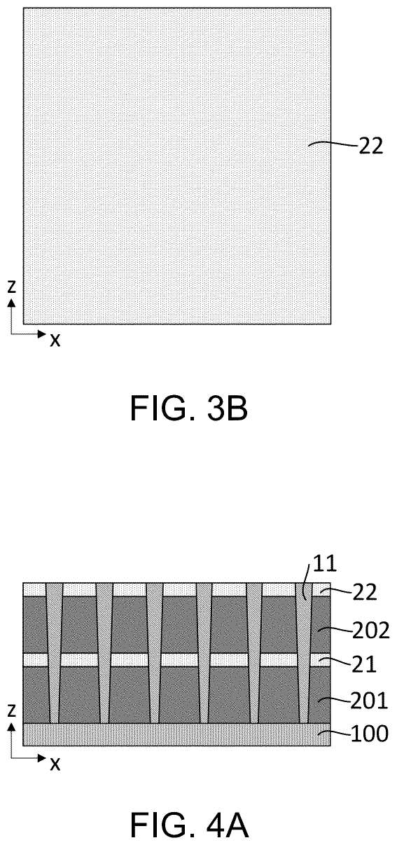

As an example, please continue to refer to step S20 in FIG. 2, FIG. 3A and FIG. 3B, the substrate 100 is provided, which may be composed of a semiconductor material, an insulating material, a conductive material, or any combination thereof. The substrate 100 is a semiconductor structure that provides mechanical support and electrical properties for the fabrication of the semiconductor device. The substrate 100 may be a single-layer structure or a multi-layer structure. For example, the substrate 100 may be a III/V semiconductor substrate 100 or a II/VI semiconductor substrate 100. The person skilled in the art can choose a type of the substrate 100 based on a type of a transistor or a semiconductor structure formed on the substrate 100, therefore, the type of the substrate 100 should not limit the scope of protection of the present disclosure.

Please continue to refer to FIG. 3A and FIG. 3B. A deposition process and/or a spin on glass coating (SOG) process may be used to form the first sacrificial layer 201 on a top surface of the substrate 100. Then, a deposition process is used to form the first support layer 21 on the first sacrificial layer 201. The preparation process of the first sacrificial layer 201 may be repeated to form the second sacrificial layer 202 on the first support layer 21. The preparation process of the first support layer 21 may be repeated to form the second support layer 22 on the second sacrificial layer 202.

Exemplarily, a material of the first sacrificial layer 201 may include silicon oxide, silicon nitride (SiNₓ), aluminum oxide (AlOₓ), silicon carbide (SiC), or the like. For example, the material of the first sacrificial layer 201 may include silicon oxide. A material of the second sacrificial layer 202 may include silicon oxide, silicon nitride (SiNₓ), aluminum oxide (AlOₓ), silicon carbide (SiC), or the like. For example, the material of the second sacrificial layer 202 may include silicon oxide.

Exemplarily, a material of the first support layer 21 may include at least one of silicon nitride, silicon oxynitride, or silicon carbide nitride. A material of the second support layer 22 may include at least one of silicon nitride, silicon oxynitride, or silicon carbide nitride. The materials of the first support layer 21 and the second support layer 22 may be the same or different.

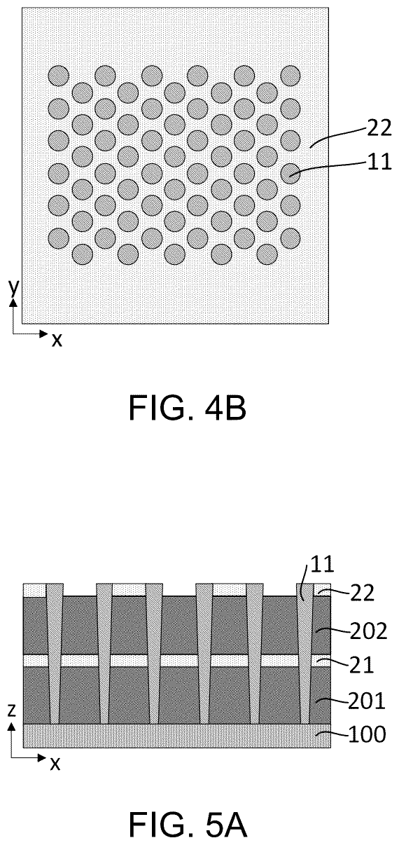

As an example, please continue to refer to step S40 in FIG. 2, FIG. 4A and FIG. 4B. In step S40, a patterned mask layer (not shown) may first be formed on the second support layer 22, where the patterned mask layer includes a pattern for defining parameters such as a shape, a position, and a dimension of a bottom electrode. The second support layer 22, the second sacrificial layer 202, the first support layer 21, and the first sacrificial layer 201 are etched based on the patterned mask layer, to obtain a plurality of through holes (not shown) which penetrate the stacked structure in the direction perpendicular to the substrate 100. Then, a deposition process may be used to form the plurality of bottom electrodes 11 in the plurality of through holes, to obtain the plurality of bottom electrodes 11 penetrating the stacked structure along the direction perpendicular to the substrate 100. A material of the bottom electrode 11 may be selected from titanium, tungsten, nickel, cobalt, silver, cobalt silicide, aluminum, palladium, copper, metal silicide, and a combination thereof.

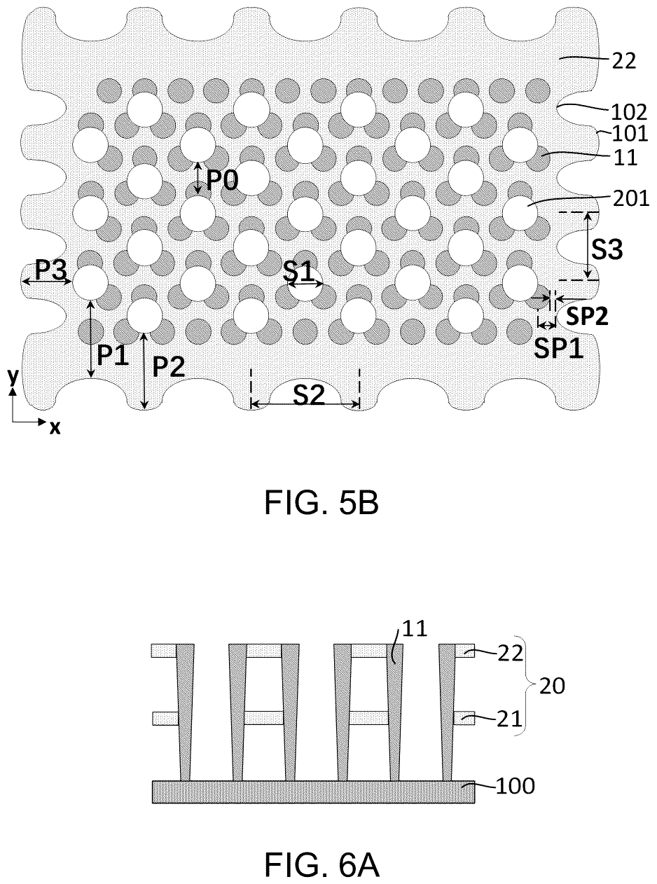

As an example, please continue to refer to steps S60 in FIG. 2, FIG. 5A and FIG. 5B. In step S60, a patterned mask may first be formed to cover a top surface of the second support layer 22 and top surfaces of the bottom electrodes 11. Where the patterned mask includes a pattern for defining parameters such as shapes, positions, dimensions of an opening and the wavy border. The stacked structure is etched based on this patterned mask, and a portion of the first support layer 21 and a portion of the second support layer 22 are removed to obtain the support layer 20 including the plurality of openings 12. The remaining first support layer 21 and the remaining second support layer 22 are used to form the support layer, and the support layer is in direct contact with the sidewalls of the plurality of bottom electrodes 11. The support layer 20 includes a wavy border; and the plurality of openings 12 are located between adjacent bottom electrodes 11, and are arranged in an array at intervals along the first direction and the second direction.

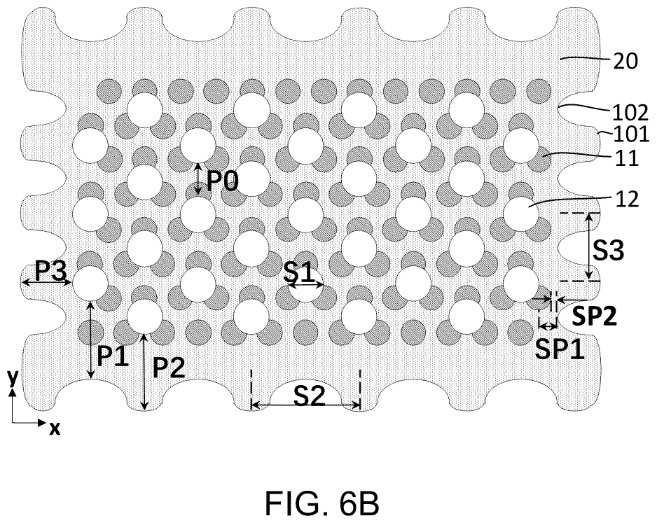

As an example, please continue to refer to step S80 in FIG. 2, FIG. 6A and FIG. 6B. In step S80, a wet etching solution may be used to remove the first sacrificial layer 201 and the second sacrificial layer 202. The wet etching solution may include a diluted hydrofluoric acid solution.

Please continue to refer to FIG. 6A and FIG. 6B. In some embodiments, the opening 12 has a first dimension S1 along the first direction, and when viewed from a top view, the wavy border includes a plurality of peaks 101 and a plurality of valleys 102; a distance between adjacent peaks 101 along the first direction has a second dimension S2, and the second dimension S2 is greater than the first dimension S1. Thus, peak regions of adjacent peaks 101 of the wavy border of the support layer 20 are aligned as much as possible with nearest openings 12 at the edge of the array region of the bottom electrodes 11. This design increases the pitch between the peak 101 of the support layer 20 and the nearest opening 12 without increasing a volume of the semiconductor structure 1000 and without reducing the cell density of the bottom electrode 11 and the support degree of the support layer 20, which improves the morphology quality of the opening pattern at the edge of the array region of the bottom electrodes 11.

Please continue to refer to FIG. 6A and FIG. 6B. In some embodiments, there is a first pitch P0 between adjacent openings 12 along the second direction; where a minimum pitch between the wavy border and a nearest opening 12 along the second direction is greater than the first pitch P0. Thus, the pitches between the peaks 101 of the wavy border of the support layer 20 and the nearest openings 12 are greater than pitches between adjacent openings 12, thereby ensuring the morphology quality of all opening patterns at the edge of the array region of the bottom electrodes 11.

Please continue to refer to FIG. 6A and FIG. 6B. In some embodiments, when viewed from a top view, the wavy border includes a plurality of peaks 101 and a plurality of valleys 102; there is a first preset pitch SP1 between the valley 102 and a nearest opening 12; and there is a second preset pitch SP2 between the valley 102 and a nearest bottom electrode 11. This design facilitates increasing the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the bottom electrode 11 and the opening pattern at the edge of the array region of the bottom electrodes 11, thereby improving the yield, performance, and reliability of the semiconductor structure 10000.

Please continue to refer to FIG. 6A and FIG. 6B. In some embodiments, the wavy border includes a first wavy border extending along the first direction and a second wavy border extending along the second direction, which facilitates arranging the sidewall of the support layer 20 surrounding the array region of the bottom electrodes 11 as the wavy border, thereby improving the morphology quality of the adjacent openings 12 of the sidewall of the support layer 20 surrounding the array region of the bottom electrodes 11.

Please continue to refer to FIG. 6A and FIG. 6B. In some embodiments, the second dimension S2 spans three bottom electrodes 11 along the first direction, which facilitates the placement of centers of two openings 12 at peak regions of two adjacent peaks 101 of the support layers 20 along the first direction. This design increases the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11 and reduces the morphology designing complexity of the wavy border of the support layer 20.

Please continue to refer to FIG. 6A and FIG. 6B. In some embodiments, a distance between adjacent peaks 101 of the first wavy border has the second dimension S2, and a distance between adjacent peaks 101 of the second wavy border has a third dimension S3. Among them, the first dimension S1<the third dimension S3<the second dimension S2. This design facilitates setting the morphology of the wavy border of the support layer 20 according to the distribution of the openings 12 in the array region of the bottom electrodes 11, so that adjacent peaks 101 of the first wavy border extending along the first direction span three bottom electrodes 11, and adjacent peaks 101 of the second wavy border extending along the second direction span three bottom electrodes 11.

The semiconductor structure preparation method in the above embodiments involves forming the plurality of bottom electrodes 11 which penetrate the stacked structure along the direction perpendicular to the substrate 100, where the stacked structure includes the first sacrificial layer 201, the first support layer 21, the second sacrificial layer 202, and the second support layer 22 stacked in sequence along the direction away from the substrate 100; and then forming the plurality of openings 12 between adjacent bottom electrodes 11, where the openings 12 are arranged in the array at intervals along the first direction and the second direction. Thus, the support layer 20 which directly contacts with the sidewalls of the plurality of bottom electrodes 11 is obtained after removing the first sacrificial layer 201 and the second sacrificial layer 202. Where the plurality of bottom electrodes 11 are supported by using the support layer 20, which ensures that the array of bottom electrodes 11 including the plurality of openings 12 is firmly standing on the substrate 100. The support layer is arranged to include the wavy border, which facilitates increasing the pitch between the peak 101 of the support layer 20 and the nearest opening 12 without increasing a volume of the semiconductor structure 1000 and without reducing the cell density of the bottom electrode 11 and the support degree of the support layer 20. This improves the morphology quality of the opening pattern at the edge of the array region of the bottom electrodes 11, thereby improving the yield, performance, and reliability of the semiconductor structure 100.

It should be understood that although the various steps in the flowchart of FIG. 2 are displayed in an order indicated by the arrows, these steps are not necessarily executed in the order indicated by the arrows. Unless explicitly stated otherwise herein, there is no strict order limit for the execution of these steps, and they can be executed in other orders. Furthermore, although at least a portion of the steps in FIG. 2 may include multiple steps or stages, these steps or stages may not necessarily be executed at the same time, but may be executed at different times. The order of execution of these steps or stages is not necessarily sequential, but may alternate or rotate with other steps or at least a portion of steps or stages of other steps.

It should be noted that, for the sake of conciseness of the specification, in the schematic structural diagrams provided in the embodiments herein, unless a corresponding cross-sectional structural schematic diagram is separately provided, the schematic structural diagrams of the structures from different perspectives related to the inventive point of the embodiments of the present disclosure may be referenced with each other.

The various technical features of the above embodiments can be combined arbitrarily. For the sake of conciseness, not all possible combinations of the various technical features of the above embodiments have been described. However, as long as there is no contradiction in the combination of these technical features, all such combinations shall be deemed to fall within the scope of the specification.

The above embodiments only illustrate several implementations of the present disclosure, and they are described in relatively specific and detailed terms, but should not be construed as limiting the scope of the patent application. It should be pointed out that for a person ordinary skill in the art, various modifications and improvements can be made without departing from the concept of the present disclosure, which shall fall within the protection scope of the present disclosure. Therefore, the protection scope of the present disclosure shall be subject to the appended claims.

What is claimed is:

1. A semiconductor structure, comprising:
a substrate;
a plurality of bottom electrodes located on the substrate;
a support layer, directly contacting with sidewalls of the plurality of bottom electrodes, wherein the support layer comprises a wavy border;
a plurality of openings located between adjacent bottom electrodes, and arranged in an array at intervals along a first direction and a second direction, wherein the opening has a first dimension;
wherein when viewed from a top view, the wavy border comprises a plurality of peaks and a plurality of valleys, with a distance between adjacent peaks having a second dimension, and the second dimension is greater than the first dimension.

2. The semiconductor structure according to claim 1, wherein the wavy border comprises a first wavy border extending along the first direction and a second wavy border extending along the second direction.

3. The semiconductor structure according to claim 1, wherein the second dimension spans three of the bottom electrodes along the first direction.

4. The semiconductor structure according to claim 2, wherein a distance between adjacent peaks of the first wavy border has the second dimension; and
a distance between adjacent peaks of the second wavy border has a third dimension; wherein the first dimension<the third dimension<the second dimension.

5. The semiconductor structure according to claim 1, wherein there is a first pitch between adjacent openings along the second direction;
wherein a minimum pitch between the wavy border and a nearest opening along the second direction is greater than the first pitch.

6. The semiconductor structure according to claim 1, wherein there is a first pitch between adjacent openings along the second direction;
wherein a maximum pitch between the wavy border and a nearest opening along the first direction is greater than the first pitch.

7. The semiconductor structure according to claim 1, wherein there is a first preset pitch between the valley and a nearest opening;
and there is a second preset pitch between the valley and a nearest bottom electrode.

8. A semiconductor structure, comprising:
a substrate;
a plurality of bottom electrodes located on the substrate;
a support layer, directly contacting with sidewalls of the plurality of bottom electrodes, wherein the support layer comprises a wavy border;
a plurality of openings located between adjacent bottom electrodes, and arranged in an array at intervals along a first direction and a second direction;
wherein when viewed from a top view, the wavy border comprises a plurality of peaks and a plurality of valleys, and there is a first preset pitch between the valley and a nearest opening;
there is a second preset pitch between the valley and a nearest bottom electrode;
wherein the first preset pitch is greater than the second preset pitch.

9. The semiconductor structure according to claim 8, wherein the opening has a first dimension along the first direction;
a distance between adjacent peaks along the first direction has a second dimension, and the second dimension is greater than the first dimension.

10. The semiconductor structure according to claim 8, wherein there is a first pitch between adjacent openings along the second direction;
wherein a minimum pitch between the wavy border and a nearest opening along the second direction is greater than the first pitch.

11. A semiconductor structure, comprising:
a substrate;
a plurality of bottom electrodes located on the substrate;
a support layer, directly contacting with sidewalls of the plurality of bottom electrodes, wherein the support layer comprises a wavy border;
a plurality of openings located between adjacent bottom electrodes, and arranged in an array at intervals along a first direction and a second direction, wherein there is a first pitch between adjacent openings;
wherein a minimum pitch between the wavy border and a nearest opening along the second direction is greater than the first pitch.

12. The semiconductor structure according to claim 11, wherein the opening has a first dimension along the first direction;
when viewed from a top view, the wavy border comprises a plurality of peaks and a plurality of valleys;
wherein a distance between adjacent peaks along the first direction has a second dimension, and the second dimension is greater than the first dimension.

13. The semiconductor structure according to claim 11, wherein when viewed from a top view, the wavy border comprises a plurality of peaks and a plurality of valleys, and there is a first preset pitch between the valley and a nearest opening;
there is a second preset pitch between the valley and a nearest bottom electrode.
